(19) United States
(12) Patent Application Publication
(10) Pub. No.: US 2024/0263342 A1
(43) Pub. Date: Aug. 8, 2024

(54) APPARATUS FOR MANUFACTURING SINGLE CRYSTAL

(71) Applicant: SHIN-ETSU HANDOTAI CO., LTD., Tokyo (JP)

(72) Inventors: Hirotaka TAKAHASHI, Nishigo-mura (JP); Suguru MATSUMOTO, Nishigo-mura (JP); Takahide ONAI, Nishigo-mura (JP); Kosei SUGAWARA, Nishigo-mura (JP)

(73) Assignee: SHIN-ETSU HANDOTAI CO., LTD., Tokyo (JP)

(21) Appl. No.: 18/290,167

(22) PCT Filed: Feb. 28, 2022
(86) PCT No.: PCT/JP2022/008417

§ 371 Date: Nov. 10, 2023

(30) Foreign Application Priority Data
May 28, 2021 (JP) 2021-090565

(51) Int. Cl. C30B 15/10; C30B 15/00; C30B 15/20

(52) U.S. Cl. CPC C30B 15/10; C30B 15/002; C30B 15/20

(57) ABSTRACT

The present invention is an apparatus for manufacturing a single crystal by growing a single crystal according to a Czochralski method, the apparatus includes a main chamber configured to house a crucible configured to accommodate a raw-material melt and a heater configured to heat the raw-material melt, a pulling chamber being continuously provided at an upper portion of the main chamber and configured to accommodate a single crystal grown and pulled, and a cooling cylinder extends from at least a ceiling portion of the main chamber toward a surface of the raw material melt to surround the single crystal being pulled. The cooling cylinder is configured to be forcibly cooled with a coolant. The apparatus includes a first auxiliary cooling cylinder fitted inside of the cooling cylinder, and a second auxiliary cooling cylinder threadedly connected to the outside of the first auxiliary cooling cylinder from a side of a lower end. A gap between a bottom surface of the cooling cylinder and a top surface of the second auxiliary cooling cylinder is 0 mm or more to 1.0 mm or less. This provides an apparatus for manufacturing a single crystal which can increase growth rate of the single crystal by efficiently cooling the single crystal being grown.

### TECHNICAL FIELD

The present invention relates to an apparatus for manufacturing a single crystal, such as a silicon single crystal, according to a Czochralski method.

### BACKGROUND ART

Semiconductor substrates, such as silicon and gallium arsenide, are constituted of single crystals and used for memories of small to large computers, for example. Meanwhile, there are demands for storage devices having a larger capacity, lower cost, and higher quality.

Conventionally, as one of single crystal manufacturing methods for manufacturing a single crystal to satisfy these demands for semiconductor substrates, a Czochralski method (CZ method) is known in which a seed crystal is dipped into a semiconductor raw material in a molten state accommodated in a crucible and then pulled up, so that a single crystal with large diameter and high quality is manufactured.

Hereinafter, a conventional apparatus for manufacturing a single crystal according to a CZ method will be described by exemplifying a growth of a silicon single crystal by reference to FIG. 4.

In an apparatus 400 for manufacturing a single crystal (conventional example) used in growing a single crystal according to a CZ method, a quartz crucible 3, a graphite crucible 4, a heater 2, and a heat insulating material 18 is provided in the main chamber 1 in which the single crystal 6 (hereinafter, may be simply referred to as the single crystal) is grown. The quartz crucible 3 generally accommodates a raw-material melt 5 and can move upwardly and downwardly. The graphite crucible 4 supports the quartz crucible 3. The heater 2 is provided to surround the quartz crucible 3 and the graphite crucible 4. The heat insulating material 18 is provided so as to surround the heater 2. A pulling chamber 7 for accommodating and taking out the grown single crystal 6 is continuously provided to an upper portion of the main chamber 1.

The apparatus 400 for manufacturing the single crystal can further include a gas inlet 11, a gas outlet 12, a cooling cylinder 13, an auxiliary cooling cylinder 14, and a heat shielding member 17.

When the single crystal 6 is manufactured using the apparatus 400 for manufacturing a single crystal 6, a seed crystal 8 is immersed in the raw-material melt 5 and carefully pulled upward while being rotated to grow the single crystal 6 in the form of a rod. Meanwhile, the crucible 3 and the crucible 4 are elevated according to the crystal growth to maintain the melt surface at a constant height all the time so that desired diameter and crystal quality are obtained.

Moreover, when the single crystal 6 is grown, the seed crystal 8 attached to a seed crystal holder 9 is immersed in the raw-material melt, and then a wire 10 is carefully wound up while the seed crystal 8 is rotated in a desired direction with a pulling mechanism (not shown) to grow the single crystal 6 at a tip end portion of the seed crystal 8.

In the manufacturing of single crystals 6 according to the CZ method described above, Grown-in defects formed in the single crystal can be controlled by a ratio between a temperature gradient in the crystal and the pulling rate (growth rate) of the single crystal, and a defect-free single crystal 6 can be pulled up by controlling the ratio (see Patent document 1).

Thus, the enhancement of the cooling effect on the single crystal 6 during the growth is important in manufacturing a defect-free crystal and also in improving productivity by increasing the growth rate of the single crystal 6.

### CITATION LIST

### Patent Literature

Patent Document 1: JP H11-157996 A
Patent Document 2: JP 2009-161416 A
Patent Document 3: JP 2020-152612 A
Patent Document 4: JP 2014-43386 A
Patent Document 5: JP 6825728 B

### SUMMARY OF INVENTION

### Technical Problem

Consequently, as a method to efficiently cool a single crystal, a method in which an auxiliary cooling cylinder having axial slits and made of such as graphite material is fitted to a water-cooled cooling cylinder placed around the crystal and extended toward a melt surface is proposed (Patent Document 2). However, in this method, there is such a problem that adhesion between the water-cooled cooling cylinder and the auxiliary cooling cylinder is insufficient, and efficient exhaust of heat generated by the crystal is difficult.

In the circumstances, Patent Document 3 proposes a method to push a diameter enlargement member into an auxiliary cooling cylinder with axial slits to bring a cooling cylinder into tight contact with the auxiliary cooling cylinder. Improved contact with the auxiliary cooling cylinder enables improved heat transfer from the auxiliary cooling cylinder to the cooling cylinder, and a pulling rate of a crystal can be improved.

Furthermore, FIG. 2 in Patent Document 4 discloses an HZ structure in which an inner surface of a cooling cylinder tightly adheres with an auxiliary cooling cylinder and a bottom surface of the cooling cylinder facing a melt surface is covered by a heat-shielding member.

Moreover, in Patent Document 5, to meet further improvement of a growth rate of a crystal, there is proposed a structure in which the bottom surface of the cooling cylinder facing the raw-material melt is covered with a cover protruding from the inside toward the outside of an auxiliary cooling cylinder thereby being cooled down so as to efficiently cool a crystal being pulled. However, in this method, distance and adhesion are determined by a dimensional tolerance of the bottom surface of the cooling cylinder and the cover of the auxiliary cooling cylinder, thus there is such a problem that a stable increase of a crystal growth rate is difficult. In some cases, the cooling cylinder and the cover are fitted so firmly and get damaged by thermal expansion during an operation thereby making continuous operation difficult. Consequently, a measure is necessary to appropriately control the distance between the bottom surface of the cooling cylinder and the top surface of the cover of the auxiliary cooling cylinder while bringing the inner surface of the cooling cylinder and an outer surface of the auxiliary cooling cylinder in close contact, so as to achieve a safe and stable increase of the growth rate regardless of dimension tolerance.

The present invention has been made to solve the above-described problems. An object of the present invention is to provide an apparatus for manufacturing a single crystal enabling an efficient cooling of the growing single crystal, and thereby an increased growth rate of the single crystal.

### Solution to Problem

To solve the problem, the present invention provides an apparatus for manufacturing a single crystal by growing a single crystal according to a Czochralski method, the apparatus comprising:
a main chamber configured to house
   a crucible configured to accommodate a raw-material melt, and
   a heater configured to heat the raw-material melt;
a pulling chamber continuously provided at an upper portion of the main chamber and configured to accommodate a single crystal grown and pulled; and
a cooling cylinder extending from at least a ceiling portion of the main chamber toward a surface of the raw material melt to surround the single crystal being pulled, the cooling cylinder being configured to be forcibly cooled with a coolant;
wherein the apparatus comprises
a first auxiliary cooling cylinder fitted inside of the cooling cylinder; and
a second auxiliary cooling cylinder threadedly connected to an outside of the first auxiliary cooling cylinder from a side of a lower end, and
a gap between a bottom surface of the cooling cylinder and a top surface of the second auxiliary cooling cylinder is 0 mm or more to 1.0 mm or less.

In such apparatus manufacturing for the single crystal, the second auxiliary cooling cylinder threadedly connected to an outside of the first auxiliary cooling cylinder from a side of a lower end thereof, thereby a gap between the bottom surface of the cooling cylinder, which faces the surface of the raw material melt, and the top surface of the second auxiliary cooling cylinder can be adjusted regardless of dimension tolerance. Consequently, the growth rate of the crystal is stably increased.

Furthermore, by setting the gap between the bottom surface of the cooling cylinder and the top surface of the second auxiliary cooling cylinder from 0 mm or more to 1.0 mm or less, heat generated from the single crystal during growth can be efficiently exhausted, and the increased growth rate of the crystals can be achieved.

A material for the first auxiliary cooling cylinder and the second auxiliary cooling cylinder is preferably any one of graphite material, carbon composite, stainless steel, molybdenum, and tungsten.

By using the first auxiliary cooling cylinder and second auxiliary cooling cylinder made of such materials, radiant heat from the crystal can be efficiently absorbed and the heat can be efficiently transferred to the cooling cylinder.

A lower end of the second auxiliary cooling cylinder is preferably located lower toward the raw material melt surface than a lower end of the first auxiliary cooling cylinder.

Hence, a further significant increase in the crystal growth rate is achieved.

It is preferable that a material for the first auxiliary cooling cylinder and the second auxiliary cooling cylinder is a graphite material, and the apparatus for manufacturing the single crystal further includes a diameter enlargement member fitted inside of the first auxiliary cooling cylinder so as to bring the first auxiliary cooling cylinder into tightly contact with the cooling cylinder.

The thermal conductivity of graphite material is equal to or higher than that of metal and the emissivity of the graphite is also higher than that of metal, thus the first auxiliary cooling cylinder and the second auxiliary cooling cylinder made of graphite material can efficiently absorb the radiant heat from the crystal more and efficiently transfer the heat to the cooling cylinder.

In addition, a diameter enlargement member is fitted inside of the first auxiliary cooling cylinder so as to bring the first auxiliary cooling cylinder into tightly contact with the cooling cylinder, consequently, the heat transfer from the first auxiliary cooling cylinder to the cooling cylinder is further improved, and the pulling rate of the crystal further is further improved.

### Advantageous Effects of Invention

As described above, an inventive apparatus for manufacturing a single crystal comprises a cooling cylinder being configured to be forcibly cooled a first auxiliary cooling cylinder fitted inside of the cooling cylinder; wherein a second auxiliary cooling cylinder threadedly connected to an outside of the first auxiliary cooling cylinder from a side of a lower end thereof, and a gap between a bottom surface of the auxiliary cooling cylinder, which faces a surface of a raw material melt, and a top surface of the second auxiliary cooling cylinder is 0 mm or more to 1.0 mm or less. In this apparatus, heat generated from the crystal can be efficiently discarded, and the growth rate of the crystal can be increased.

### BRIEF DESCRIPTION OF DRAWINGS

FIG. 1 is a schematic cross-sectional view showing one example of an inventive apparatus for manufacturing a single crystal.

FIG. 2 is a schematic cross-sectional view showing another example of the inventive apparatus for manufacturing a single crystal.

FIG. 3 is a schematic cross-sectional view showing an apparatus for manufacturing a single crystal used in Comparative Example 1.

FIG. 4 is a schematic cross-sectional view showing an example of an apparatus for manufacturing a single crystal generally used.

FIG. 5 is a graph showing a gap between a bottom surface of a cooling cylinder and a top surface of the second auxiliary cooling cylinder (a top surface of a cover of the first auxiliary cooling cylinder) in Example 1 and Comparative Example 1.

FIG. 6 is a graph showing a crystal growth rate of each of defect-free crystals obtained in Example 1 and Comparative Example 1.

FIG. 7 is a graph showing a relation between a gap between a bottom surface of a cooling cylinder t and a top surface of the second auxiliary cooling cylinder, and the growth rate of each of crystals, obtained in Example 3 and Comparative Example 2.

### DESCRIPTION OF EMBODIMENTS

As noted above, it has been known that in single crystal manufacturing according to CZ method, increasing the growth rate of a single crystal is one major approach for productivity improvement and cost reduction. It also has been known that the single-crystal growth rate can be increased by efficiently discarding radiant heat from the single crystal, and by increasing the temperature gradient in the crystal.

Thus, heat generated from a single crystal is efficiently discarded by virtue of, as described in Patent Document 5, a covering of a bottom surface of the cooling cylinder facing the raw material melt with a cover of the auxiliary cooling cylinder protruding from the inside of the cooling cylinder to the outside while fitting an auxiliary cooling cylinder made of, for example, graphite material into a cooling cylinder that surrounds a single crystal being pulled up and is forcibly cooled with a coolant.

As shown in Patent Document 5, the closer the distance between the bottom surface of the cooling cylinder and the auxiliary cooling cylinder is, the higher the growth rate of the crystal. The distance between the bottom surface of the cooling cylinder and the auxiliary cooling cylinder is determined by the tolerance of the cooling cylinder and the auxiliary cooling cylinder, hence there is a challenge in increasing the crystal growth rate stably. When a distance between the cooling cylinder and the cover of the auxiliary cooling cylinder is extremely close, there is a case where the cooling cylinder and the cover are fitted so firmly and can be damaged during an operation thereby making continuous operation impossible. Consequently, in order to increase the crystal growth rate stably, appropriate control of the distance between the bottom surface of the cooling cylinder and the auxiliary cooling cylinder is important.

To solve the above problem, the present inventors have earnestly studied and found out that by virtue of an apparatus for manufacturing a single crystal by growing a single crystal according to a Czochralski method, the apparatus comprises: a main chamber configured to house a crucible configured to accommodate a raw-material melt, and a heater configured to heat the raw-material melt; a pulling chamber continuously provided at an upper portion of the main chamber and configured to accommodate a single crystal grown and pulled; and a cooling cylinder extending from at least a ceiling portion of the main chamber toward a surface of the raw material melt to surround the single crystal being pulled, the cooling cylinder being configured to be forcibly cooled with a coolant; wherein the apparatus comprises a first auxiliary cooling cylinder fitted inside of the cooling cylinder; and a second auxiliary cooling cylinder threadedly connected to an outside of the first auxiliary cooling cylinder from a side of a lower end, a distance between the cooling cylinder and the auxiliary cooling cylinder can be appropriately controlled, the auxiliary cooling cylinder can be efficiently cooled, radiant heat from a single crystal can be efficiently discarded, and thereby a significant improvement of a growth rate of the single crystal can be achieved. Based on this finding, the present invention has been completed.

Accordingly, the present invention is an apparatus for manufacturing a single crystal by growing a single crystal according to a Czochralski method, the apparatus comprises:
a main chamber configured to house
a crucible configured to accommodate a raw-material melt, and
a heater configured to heat the raw-material melt;
a pulling chamber continuously provided at an upper portion of the main chamber and configured to accommodate a single crystal grown and pulled; and
a cooling cylinder extending from at least a ceiling portion of the main chamber toward a surface of the raw material melt to surround the single crystal being pulled, the cooling cylinder being configured to be forcibly cooled with a coolant;
wherein the apparatus comprises
a first auxiliary cooling cylinder fitted inside of the cooling cylinder; and
a second auxiliary cooling cylinder threadedly connected to an outside of the first auxiliary cooling cylinder from a side of a lower end, and
a gap between a bottom surface of the cooling cylinder and a top surface of the second auxiliary cooling cylinder is 0 mm or more to 1.0 mm or less.

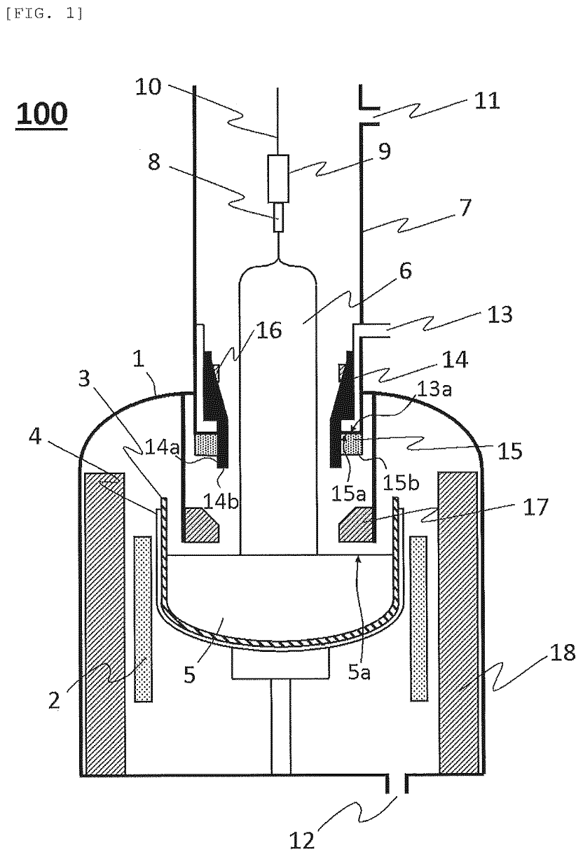

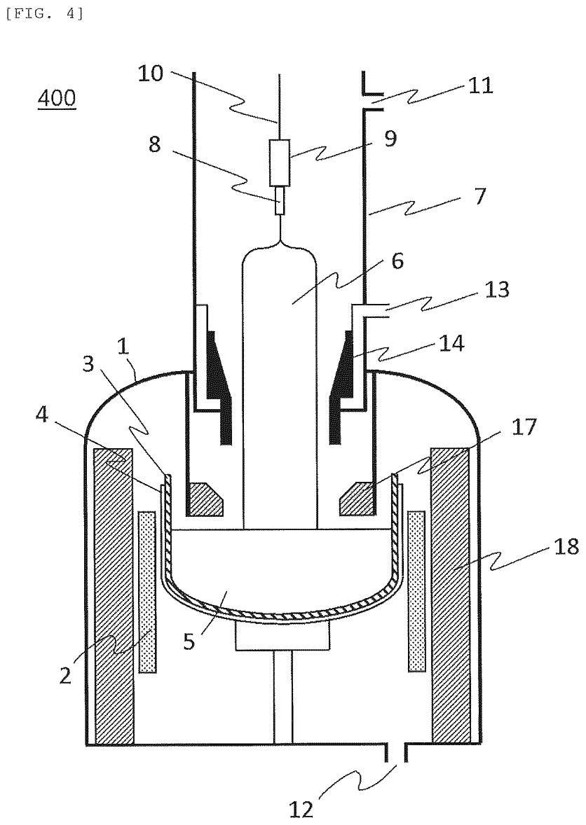

Hereinafter, one example of embodiments of the present invention will be described by reference with FIG. 1. However, the present invention is not limited thereto. Note that the descriptions of the same features as in the conventional apparatus shown in FIG. 4 may be omitted as appropriate.

An inventive apparatus 100 for manufacturing a single crystal shown in FIG. 1 is a single-crystal manufacturing apparatus including a main chamber 1 configured to house a quartz crucible 3 which is configured to accommodate a raw-material melt 5 and graphite crucible 4, and a heater 2 configured to heat the raw-material melt 5; a pulling chamber 7 continuously provided at an upper portion of the main chamber 1 and configured to accommodate a single crystal 6 grown and pulled; a cooling cylinder 13 extending from at least a ceiling portion of the main chamber 1 toward a raw material melt surface 5a to surround the single crystal 6 being pulled, a cooling cylinder 13 being configured to be forcibly cooled with a coolant; a first auxiliary cooling cylinder 14 fitted inside of the cooling cylinder 13; and a second auxiliary cooling cylinder 15 threadedly connected to an outside of the first auxiliary cooling cylinder 14 from the side of the lower end 14b.

In the apparatus 100 for manufacturing the single crystal, by threadedly connecting the second auxiliary cooling cylinder 15 to the outside of the first auxiliary cooling cylinder 14 from the side of the lower end thereof, a gap between a bottom surface 13a of the cooling cylinder 13, which faces the raw material melt 5, and the top surface 15a of the second auxiliary cooling cylinder 15 can be adjusted. More precisely, the second auxiliary cooling cylinder 15 is threadedly connected to the outside of the portion 14a of the first auxiliary cooling cylinder 14 that is fitted inside the cooling cylinder 13 from the side of the lower end 14b of this portion 14a, the portion 14a of the first auxiliary cooling cylinder 14 extending toward the surface 5a of the raw melt. Thus, as shown in FIG. 1, the bottom surface 13a of the cooling cylinder 13 and the top surface 15a of the second auxiliary cooling cylinder 15 are facing each other. By tightening the second auxiliary cooling cylinder 15 upward or lowering the second auxiliary cooling cylinder 15 toward the side of the lower end 14b in the state where the second auxiliary cooling cylinder 15 is threadedly connected to an outside of the first auxiliary cooling cylinder 14 from the side of the lower end 14b, a gap between the bottom surface 13a of the cooling cylinder 13 and the top surface 15a of the second auxiliary cooling cylinder 15 can be stably and easily adjusted regardless of dimensional tolerance.

In the present invention, the gap between the bottom surface 13a of the cooling cylinder 13 and the top surface 15a of the second auxiliary cooling cylinder 15 is 0 mm or more to 1.0 mm or less. When the gap between the bottom surface 13a of the cooling cylinder 13 and the top surface 15a of the second auxiliary cooling cylinder 15 exceeds 1.0 mm, the first auxiliary cooling cylinder and the second auxiliary cooling cylinder do not cool down sufficiently, thus the increase of the growth rate of single crystal cannot be achieved. When the gap is 1.0 mm or less, a significant increase in the growth rate of the single crystal can be achieved. As shown in FIG. 1, when the gap between the bottom surface 13a of the cooling cylinder 13 and the top surface 15a of the second auxiliary cooling cylinder 15 is 0 mm, both the surfaces contact and closely adhere with each other, then the crystal growth rate is maximized.

Furthermore, to efficiently absorb radiant heat from the crystal and efficiently conduct the heat to the cooling cylinder, in the present invention, it is preferable that a material(s) for the first auxiliary cooling cylinder 14 and the second auxiliary cooling cylinder 15 are any one or more of a graphite material, carbon composite, stainless steel, molybdenum, and tungsten. Among the metals described above, graphite material having thermal conductivity equal to or higher than metal and emissivity also higher than that of metal is especially preferable.

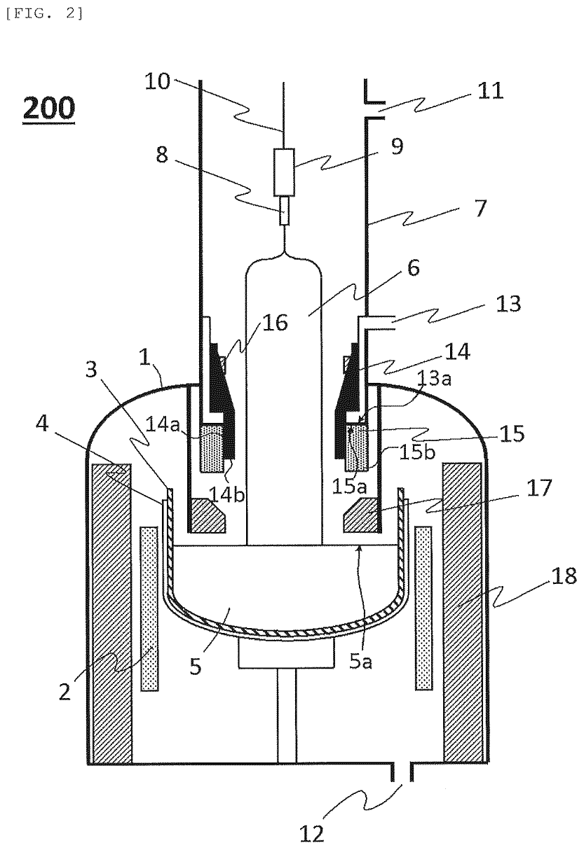

The lower end 15b of the second auxiliary cooling cylinder 15 is desirably located lower toward the surface 5a of raw material melt than the lower end 14b of the first auxiliary cooling cylinder 14 as, for example, the apparatus 200 for manufacturing a single crystal shown in FIG. 2. By this means, the second auxiliary cooling cylinder 15, which is cooled by the cooling cylinder 13, faces single crystal 6 being pulled, consequently, the heat generated from the crystal can be efficiently discarded, and a significant increase in the growth rate can be achieved.

An apparatus 100 for manufacturing a single crystal shown in FIG. 1 and an apparatus 200 for manufacturing a single crystal shown in FIG. 2 further include a diameter enlargement member 16 fitted inside of the first auxiliary cooling cylinder 14. By fitting the diameter enlargement member 16 to the first auxiliary cooling cylinder 14, adhesiveness between the cooling cylinder 13 and the auxiliary cooling cylinder 14 can be enhanced, and heat transfer from the first auxiliary cooling cylinder 14 to the cooling cylinder 13 can be improved and the pulling rate of the crystal can be further increased.

### EXAMPLE

Hereinafter, the present invention will be specifically described with reference to Examples and Comparative Examples. However, the present invention is not limited thereto.

### Example 1

Single crystals were manufactured by using four units of apparatus 100 for manufacturing a single crystal as shown in FIG. 1. A cooling cylinder 13 and a first auxiliary cooling cylinder 14 were adhered each other to by using a diameter enlargement member 16. A second auxiliary cooling cylinder 15 is threadedly connected to the outside of the first auxiliary cooling cylinder 14 from the side of the lower end 14b. By actual measurements, it was confirmed that the bottom surface 13a of the cooling cylinder 13, which faces a raw material melt 5, adhered to the top surface 15a of the second auxiliary cooling cylinder 15. In other words, a gap between the bottom surface 13a of the cooling cylinder 13 and the top surface 15a of the second auxiliary cooling cylinder 15 was 0 mm in Example 1. The second auxiliary cooling cylinder 15 was configured to cover an entire area on the bottom surface 13a of the cooling cylinder 13. An axial length of the second auxiliary cooling cylinder 15 was set to 70 mm and the lower end 15b of the second auxiliary cooling cylinder 15 was set to locate 50 mm above the lower end 14b of the first auxiliary cooling cylinder 14. As a material for the first auxiliary cooling cylinder 14 and the second auxiliary cooling cylinder 15, a graphite material having thermal conductivity equal to or higher than metal and emissivity also higher than that of metal was used.

Using such apparatus 100 for manufacturing a single crystal, a single crystal 6 was grown and a growth rate with completely defect-free was found.

A margin for the growth rate to obtain a defect-free crystal is very narrow, an appropriate growth rate thereof is easy to determine. An evaluation for the presence or absence of a defect in the single crystal was performed by slicing the single crystal to obtain a sample, then performing a selective etching to evaluate whether there was a defect-free area.

### Example 2

Single crystals were manufactured by using four units of apparatus 200 for manufacturing a single crystal as shown in FIG. 2. The single crystals were manufactured by using the same apparatus and conditions as described in Example 1, except that the lower end of the second auxiliary cooling cylinder 15 is set to locate 50 mm under the lower end 14b of the first auxiliary cooling cylinder 14.

### Comparative Example 1

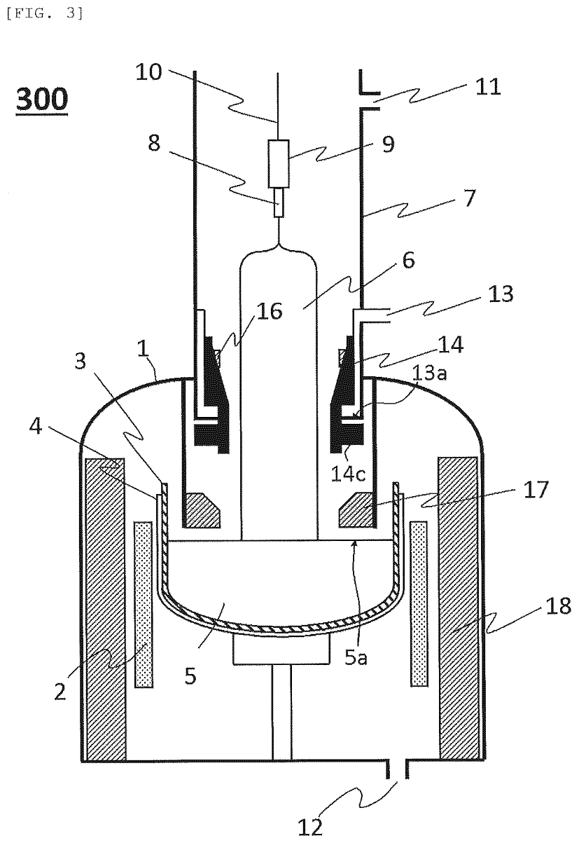

Single crystal were manufactured by using ten units of apparatus 300 for manufacturing a single crystal as shown in FIG. 3. A first auxiliary cooling cylinder 14 was shaped to have a cover 14c that covered a bottom surface 13a of a cooling cylinder 13 facing the raw material melt 5 by protruding from the inside to the outside of the cooling cylinder 13. In this case, a gap between a bottom surface 13a of the cooling cylinder 13, which faced the raw material melt 5, and a top surface 15a of a second auxiliary cooling cylinder 15 was designed to set 0.4 mm. Considering a dimensional tolerance, a design is impossible to make a gap any narrower. Moreover, the cover 14c had a shape to overlay the entire area of the bottom surface 13a of a cooling cylinder 13, and a thickness of the cover 14c was set to 70 mm. A gap between the bottom surface 13a of the cooling cylinder 13 and the top surface of the cover 14c of the first auxiliary cooling cylinder 14 was measured by actual measurement.

Moreover, the apparatus 300 for manufacturing a single crystal did not have the second auxiliary cooling cylinder 15 shown in FIG. 1 and FIG. 2. The single crystals were manufactured by using the same apparatus and conditions as described in Example 1, except for that condition.

### Example 3

Single crystals were manufactured by using apparatus 100 for manufacturing a single crystal as shown in FIG. 1. A gap between a bottom surface 13a of a cooling cylinder 13, which faced a raw material melt 5, and a top surface 15a of a second auxiliary cooling cylinder 15 was set to 0 to 1.0 mm by threadedly connecting, then a growth rate of a crystal was measured. The single crystal was manufactured by using the same apparatus and conditions as described in Example 1, except for that condition.

### Comparative Example 2

Single crystals were manufactured by using an apparatus 100 for manufacturing a single crystal as shown in FIG. 1. A gap between a bottom surface 13a of a cooling cylinder 13, which faced a raw material melt 5, and a top surface 15a of a second auxiliary cooling cylinder 15 was set to 1.1 to 1.4 mm by threadedly connecting, then a growth rate of the crystal was measured. The single crystal was manufactured by using the same apparatus and conditions as described in Example 1, except for that condition.

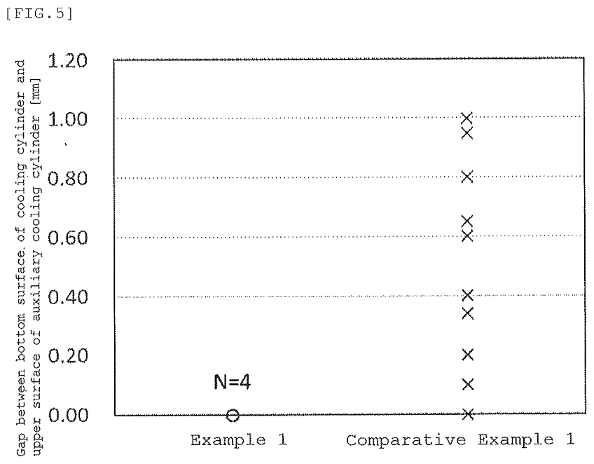

The gap, which was actually measured in Example 1, between the bottom surface 13a of the cooling cylinder 13 and the top surface 15a of the second auxiliary cooling cylinder 15 and the gap, which was actually measured in Comparative Example 1, between the bottom surface 13a of the cooling cylinder 13 and the top surface of the cover 14c of the first auxiliary cooling cylinder 14 are shown in FIG. 5. The gap was 0 mm in every operation in Example 1, on the contrary, the gap was 0 to 1.0 mm in Comparative Example 1, varied greatly due to the dimensional tolerances of the cooling cylinder 13 and the first auxiliary cooling cylinder 14.

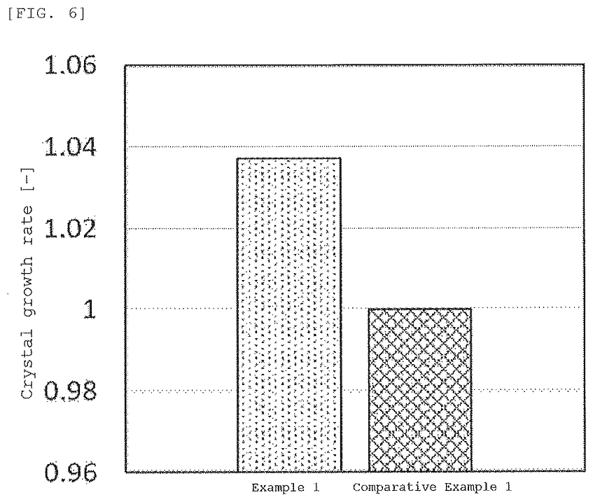

In FIG. 6, crystal growth rates for a defect-free crystal obtained from Example 1 and Comparative Example 1 were shown. Crystal growth rates of Example 1 and Comparative Example 1 are average values of all operations respectively, and are shown as relative values when the average value of the crystal growth rate of Comparative Example 1 is standardized to 1. The crystal growth rate in Example 1 increased by 3.7% compared to that of Comparative Example 1. In Comparative Example 1, due to the dimensional tolerance of the cooling cylinder 13 and the first auxiliary cooling cylinder 14, the gap between the bottom surface 13a of the cooling cylinder 13 and the top surface of the cover 14c of the first auxiliary cooling cylinder 14 varied, as shown in FIG. 5. Consequently, the average crystal growth rate was decreased. The other hand, a stable and high crystal growth rate was achieved in Example 1.

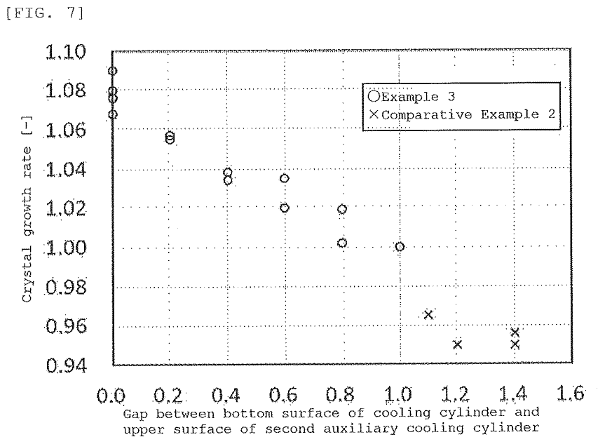

FIG. 7 shows the crystal growth rate when the gap between the bottom surface 13a of the cooling cylinder 13 and the top surface 15a of the second auxiliary cooling cylinder 15 was adjusted between 0 mm to 1.4 mm by threadedly connecting, as in Example 3 and Comparative Example 2. The crystal growth rates in FIG. 7 are shown as relative values based on a standardized growth rate in the case where the gap between the bottom surface 13a of the cooling cylinder 13 and the top surface 15a of the second auxiliary cooling cylinder 15 was adjusted to 1.0 mm as 1. When the gap was 0 mm, the crystal growth rate was a maximum value of 1.090. In contrast, when the gap was 1.1 mm or more, the crystal growth rate was 0.965, which is significantly-decreased rate. It is found that a distance between the bottom surface 13a of the cooling cylinder 13 and the second auxiliary cooling cylinder 15 was great when the gap was 1.1 mm or more, the first auxiliary cooling cylinder 14 and the second auxiliary cooling cylinder 15 were not sufficiently cooled down, and radiant heat from the single crystal was not efficiently removed. Considering this fact, it is found that when the gap between the bottom surface 13a of the cooling cylinder 13 and the top surface 15a of the second auxiliary cooling cylinder 15 is 1.0 mm or less, a remarkable increase in the crystal growth rate can be achievable.

Table 1 shown below summarizes the crystal growth rates obtained in Example 1, Example 2, and Comparative Example 1. The crystal growth rates shown in Table 1 are shown as a relative value when the average crystal growth rate in Comparative Example 1 is standardized to 1. When compared with Comparative Example 1, Example 1 exhibited an increase of 3.7%, and Example 2 exhibited an increase of 8.0% in the crystal growth rate.

TABLE 1

| Configuration | Crystal pulling rate [—] |
|---|---|
| Comparative Example 1 | 1.000 |
| Example 1 | 1.037 |
| Example 2 | 1.080 |

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. An apparatus for manufacturing a single crystal by growing a single crystal according to a Czochralski method, the apparatus comprising:
a main chamber configured to house
a crucible configured to accommodate a raw-material melt, and
a heater configured to heat the raw-material melt;
a pulling chamber continuously provided at an upper portion of the main chamber and configured to accommodate a single crystal grown and pulled; and
a cooling cylinder extending from at least a ceiling portion of the main chamber toward a surface of the raw material melt to surround the single crystal being pulled, the cooling cylinder being configured to be forcibly cooled with a coolant;
wherein the apparatus comprises
a first auxiliary cooling cylinder fitted inside of the cooling cylinder; and
a second auxiliary cooling cylinder threadedly connected to an outside of the first auxiliary cooling cylinder from a side of a lower end, and
a gap between a bottom surface of the cooling cylinder and a top surface of the second auxiliary cooling cylinder is 0 mm or more to 1.0 mm or less.

2. The apparatus for manufacturing a single crystal according to claim 1, wherein
a material for the first auxiliary cooling cylinder and the second auxiliary cooling cylinder comprises any one of a graphite material, carbon composite, stainless steel, molybdenum, and tungsten.

3. The apparatus for manufacturing a single crystal according to claim 1, wherein
a lower end of the second auxiliary cooling cylinder is located lower toward the raw material melt surface than a lower end of the first auxiliary cooling cylinder.

4. The apparatus for manufacturing a single crystal according to claim 2, wherein
a lower end of the second auxiliary cooling cylinder is located lower toward the raw material melt surface than a lower end of the first auxiliary cooling cylinder.

5. The apparatus for manufacturing a single crystal according to claim 1, wherein
a material for the first auxiliary cooling cylinder and the second auxiliary cooling cylinder is a graphite material, and
the apparatus for manufacturing a single crystal further comprises a diameter enlargement member which is fitted inside of the first auxiliary cooling cylinder, so as to bring the first auxiliary cooling cylinder into tightly contact with the cooling cylinder.

6. The apparatus for manufacturing a single crystal according to claim 2, wherein
a material for the first auxiliary cooling cylinder and the second auxiliary cooling cylinder is a graphite material, and
the apparatus for manufacturing a single crystal further comprises a diameter enlargement member which is fitted inside of the first auxiliary cooling cylinder, so as to bring the first auxiliary cooling cylinder into tightly contact with the cooling cylinder.

7. The apparatus for manufacturing a single crystal according to claim 3, wherein
a material for the first auxiliary cooling cylinder and the second auxiliary cooling cylinder is a graphite material, and
the apparatus for manufacturing a single crystal further comprises a diameter enlargement member which is fitted inside of the first auxiliary cooling cylinder, so as to bring the first auxiliary cooling cylinder into tightly contact with the cooling cylinder.

8. The apparatus for manufacturing a single crystal according to claim 4, wherein
a material for the first auxiliary cooling cylinder and the second auxiliary cooling cylinder is a graphite material, and
the apparatus for manufacturing a single crystal further comprises a diameter enlargement member which is fitted inside of the first auxiliary cooling cylinder, so as to bring the first auxiliary cooling cylinder into tightly contact with the cooling cylinder.
